(19) United States
(12) Patent Application Publication
(10) Pub. No.: US 2005/0287897 A1
(43) Pub. Date: Dec. 29, 2005

(54) Method of producing display using mask alignment method

(75) Inventors: Atsushi Tanaka, Minamiashigara-shi (JP); Koji Murayama, (US)

Correspondence Address: MILDE & HOFFBERG, LLP, 10 BANK STREET, SUITE 460, WHITE PLAINS, NY, 10606, US

(73) Assignees: CHI MEI OPTOELECTRONICS CORP.; KYOCERA CORPORATION

(21) Appl. No.: 11/159,997

(22) Filed: Jun. 23, 2005

(30) Foreign Application Priority Data
Jun. 25, 2004 (JP) 2004-187973

(51) Int. Cl. H01J 9/00

(52) U.S. Cl. 445/24

(57) ABSTRACT

A method of producing a display comprises the steps of: aligning a display substrate having a plurality of pixel patterns and a mask having a plurality of holes corresponding to the pixel patterns to measure the position between the holes of the mask and the pixel patterns of the display substrate before fixing the position between the mask and the substrate; fixing the position between the mask and the substrate and measuring the position between the holes and the pixel patterns in this situation to calculate shift levels of the position between the position measured in this step and the position measured in the first step; and adjusting the position between the mask and a second display substrate by feeding back the shift levels of the position calculated in the second step when aligning the mask and the second display substrate.

### BACKGROUND OF THE INVENTION

1. Field of the Invention

The present invention relates to a method of producing a display using a mask alignment method between a display substrate and a mask when evaporating an evaporant layer on the display substrate, such as organic electroluminescence (hereinafter referred to as OLED) and a liquid crystal via the mask.

2. Description of Related Art

A method of depositing an evaporant layer by aligning a display substrate and a mask has been generally used to form an evaporant layer on pixel patterns in the display substrate, such as OLED and liquid crystals. Vacuum evaporation, sputtering, and chemical vapor deposition (CVD) or the like are widely used as a deposition method. For example, the evaporant layer is a transparent conducting layer or a dyed resin and the like when the display substrate is a liquid crystal. The evaporant layer is an organic layer, such as a light-emitting layer or a hole-transporting layer or an electron-transporting layer when the display substrate is an OLED display substrate. The display substrate will now be described as an OLED display substrate to be simplified. An alignment with a display substrate and a mask is hereinafter simply referred to as a positioning or an alignment or a mask alignment in this specification.

More specifically, the most common method of preparing a full-colored OLED display is a method of separately forming each light-emitting material by a mask evaporation with a fine mask according to pixel patterns. The full-colored OLED display has pixel patterns in which each sub-pixel for RGB (red, green, and blue) is regularly aligned and the mask has holes to correspond to the pixel patterns. Organic layers using a mask are formed separately per sub-pixel for RGB as below.

As shown in FIGS. 7(a) to 7(g), (1) a hole-injecting layer is evaporated all over a substrate where anodes are formed via a mask for overall evaporation of the substrate. (2) Similarly, a hole-transporting layer is evaporated all over the substrate via the mask for overall evaporation of the substrate. (3) A red light-emitting layer is evaporated on red sub-pixels by aligning the holes of the precise mask having a hole for each colored sub-pixels and sub-pixels for red. (4) The holes of the mask and green sub-pixels are aligned by accomplishing small movements of the above-mentioned precise mask to evaporate a green light-emitting layer on the green sub-pixels. (5) Further, the holes of the mask and blue sub-pixels are aligned by accomplishing small movements of the above-mentioned mask to evaporate a blue light-emitting layer on the blue sub-pixels. (6) An electron-transporting layer is evaporated all over the substrate via the mask for all over evaporation of the substrate. (7) Similarly, anode layers are evaporated all over the substrate via the mask for overall evaporation of the substrate.

(Cited Document 1)

Japanese Publication No. 2003-306761 (Paragraph 19 to 20)

An alignment is conducted in a state of separating the mask and the substrate as shown in FIG. 2(a) when aligning the mask and the substrate and as shown in FIG. 2(b), a display substrate 110 is in contact with a mask 50. After that, as shown in FIG. 2(c), the position of the display substrate 110 and the mask 50 is fixed in a state closely attached to each other using a magnet chuck 12. This will be now described in detail as below.

The position of the display substrate 110 and the mask 50 is needed to be adjusted. To do that, adjustments with high precision are made in directions of X, Y, θ by accomplishing small movements of the display substrate 110 and the mask 50 respectively supported. At this time, a film may be formed on the bottom surface of the display substrate 110 in an evaporation process, so that as shown in FIG. 2(a), the display substrate 110 and the mask 50 are supported by ends of a substrate holder 16. Upon the completion of an alignment operation, as shown in FIG. 2(b), the substrate 110 is left at rest on the mask 50. At this time, the substrate and the mask are only in contact to each other because the substrate and the mask are not secured to each other.

On the other hand, as shown in FIG. 2(c), it is needed to unify the display substrate 110 and the mask 50 to be secured so that the distribution of uniform film thickness may be secured by revolving the display substrate 110 and the mask 50 in a fixed state by being closely attached to each other when forming a film. Unless the flatness of the mask and the magnet chuck is sufficient when the substrate and the mask are closely attached to each other using a magnet, there may be a change in the contact state, which leads to a shift in alignment. It is difficult to increase the flatness of the mask and it is particularly easy to cause a shift in alignment particularly when the mask has an area of not less than 1,200 cm², such as 300 mm×400 mm or the like.

Thus, the difference in the fixed conditions of the display substrate 110 and the mask 50 between the time of the completion of alignment and the time of starting a film formation has often caused a shift of the substrate at the time of actual film formation regardless of the alignment with high precision.

Therefore, in a conventional alignment, the mechanical precision of an alignment system has been adjusted with very high precision to obtain a sufficient precision so that the above-mentioned shift caused between the time of completion of the alignment operation and the time of forming a film may be minimized. However, even if a sufficient precision is obtained in the combination of specific display substrate 110 and the mask 50, in many cases, the desired precision has not been obtained when either of them is interchanged.

Further, the probability of obtaining the required precision has not been so high after re-alignment because the same alignment method is repeated, although re-alignment is possible when there is a shift in the alignment.

Under these circumstances, it has been needed to make a selection, such as a relaxation of the required precision of the alignment, an increase of the frequency of the alignment, and the removal of the substrate which is incapable of being aligned with the required precision. Accordingly, there have been extremely disadvantages in visual quality, tact time, and costs and the like in the conventional alignment.

As mentioned above, in the prior art, it has been substantially difficult to conduct an alignment with required high precision in a condition of stability in mass production processes.

There is a method of separating patterns using an inject-type nozzle without forming separately with a mask, but the light-emitting material is limited to a high-molecular material as well as problems with the emission efficiency, the life-cycle, and the productivity or the like.

Furthermore, there are a method of incorporating a colored filter into white light-emission instead of forming separately red, green, and blue colors in the light-emitting material and a method of converting into blue light-emission using a color converted layer with high-definition, but either of these methods has not solved such problems as luminous efficiency and conversion efficiency.

Thus, a separate forming process is still widely used as a method of producing full-colored OLED displays. However, in this case, as mentioned above, the precision of the alignment with the mask and the substrate has greatly effect on the visual quality, the costs, and the tact time of the display. More specifically, the displacement may occur until the start of forming a film, even if an alignment is conducted with high precision at the time of completing the alignment operation, which has caused deterioration in position accuracy or an increase in process time and the like.

It is, therefore, an object of the present invention to provide a big-screen display with high visual quality capable of speedily performing an alignment process of a display substrate and a mask with precision.

### SUMMARY OF THE INVENTION

A method of producing a display according to the present invention comprises the steps of: (1) preparing a first display substrate having a plurality of pixel patterns and a mask having a plurality of holes corresponding to the pixel patterns; (2) aligning the mask with the first display substrate and measuring the position between the holes and the pixel patterns before fixing the position between the mask and the first display substrate; (3) fixing the position between the mask and the first display substrate and measuring the position between the holes and the pixel patterns in this situation to calculate shift levels of the position between the position measured and the position measured in the second step; (4) adjusting the position between the mask and a second display substrate by feeding back the shift levels of the position calculated in the third step when aligning the mask and the second display substrate; and (5) forming an evaporant layer on each pixel pattern by depositing evaporant on the pixel patterns via the holes of the mask from an evaporating source provided on the outside of the mask.

The mask may be formed of a magnetic material and its area may be not less than 1,200 cm².

### BRIEF DESCRIPTION OF THE DRAWING

FIG. 1 is a cross sectional view showing a deposition apparatus with a mask alignment system fitted with a display substrate and a mask used in a display production method of the present invention.

FIG. 2(a) is a cross sectional view showing a deposition apparatus with a mask alignment system fitted with a display substrate and a mask when the display substrate and the mask are separated from each other.

FIG. 2(b) is a cross sectional view showing a deposition apparatus with a mask alignment system fitted with a display substrate and a mask when the display substrate is in contact the mask.

FIG. 2(c) is a cross sectional view showing a deposition apparatus with a mask alignment system fitted with a display substrate and a mask when the display substrate is closely attached to the mask.

FIG. 3(a) is a cross sectional view showing a deposition apparatus with a mask alignment system when a mask 50 is fitted.

FIG. 3(b) is a cross sectional view showing a deposition apparatus with a mask alignment system when a display substrate is attached to a mask holder.

FIG. 3 (c) is a cross sectional view showing a deposition apparatus with a mask alignment system when the display substrate is closely attached to the mask.

FIG. 3(d) is a cross sectional view showing a deposition apparatus with a mask alignment system when the display substrate and the mask are separated from each other.

FIG. 4(a) is a cross sectional view of a deposition apparatus with a mask alignment system showing the state of moving a display substrate.

FIG. 4(b) is a cross sectional view of a deposition apparatus with a mask alignment system when the display substrate is closely attached to the mask.

FIG. 4(c) is a cross sectional view of a deposition apparatus with a mask alignment system when the display substrate and the mask are closely secured to each other using a magnet chuck.

FIG. 5 is a flow chart showing a method of producing a display of the present invention. FIG. 6 is a bar graph showing effects of alignment correction of the present invention. FIG. 7(a) is a cross sectional view showing a mask and an OLED display when a hole-injecting layer is deposited.

FIG. 7(b) is a cross sectional view showing a mask and an OLED display when a hole-transporting layer is deposited.

FIG. 7(c) is a cross sectional view showing a mask and an OLED display when a red light-emitting layer is deposited.

FIG. 7(d) is a cross sectional view showing a mask and an OLED display when a green light-emitting layer is deposited.

FIG. 7(e) is a cross sectional view showing a mask and an OLED display when a blue light-emitting layer is deposited.

FIG. 7(f) is a cross sectional view showing a mask and an OLED display when an electron-transporting layer is deposited.

FIG. 7(g) is a cross sectional view showing a mask and an OLED display when a cathode layer is deposited.

### DESCRIPTION OF THE PREFERRED EMBODIMENTS

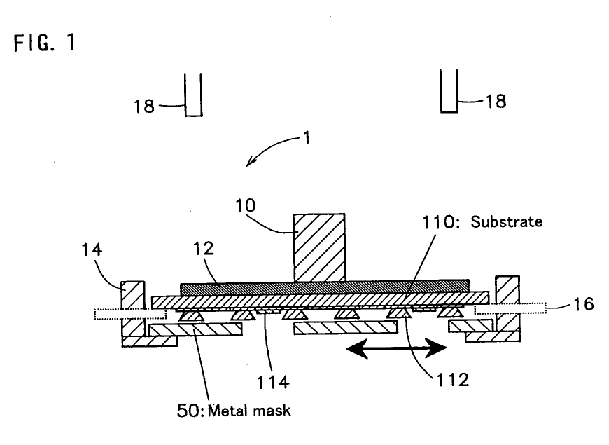

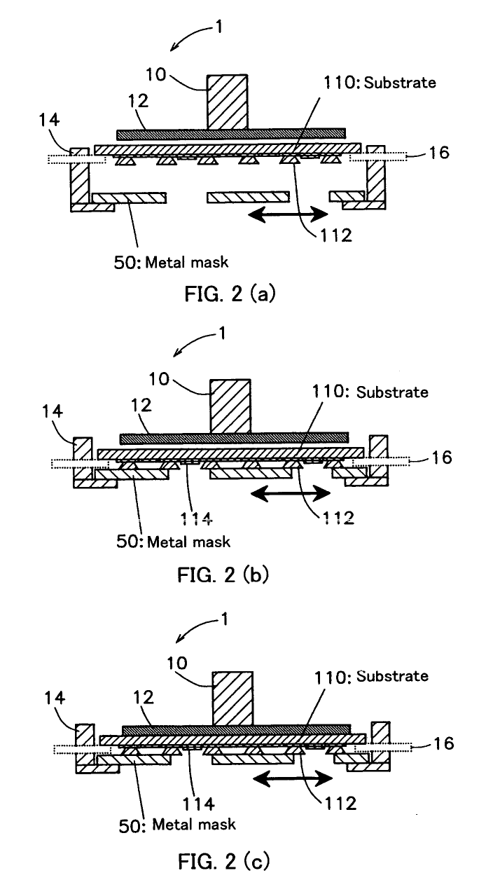

A deposition apparatus with a mask alignment system used in a method of producing a display according to the present invention may be a known apparatus as shown in FIGS. 2(a) to 2(c). For example, a deposition apparatus 1 with a mask alignment system showing its cross section in FIG. 1 is used. Accordingly, the same symbols are used for common components in the figures.

In FIG. 1, the deposition apparatus 1 with a mask alignment system comprises: a support rod 10 for connecting to a lifting and lowering device not shown in the figure at upper ends; a magnet chuck 12 for connecting to the support rod 10 at lower ends; a substrate holder 16 placed obliquely downward of the magnet chuck 12; a mask holder 14 liftably placed through holes made in the substrate holder 16; and a plurality of CCD cameras 18 placed upward to the magnet chuck 12.

A mask 50 is placed on the mask holder 14 at its edges during mask alignment and deposition processes of the present invention. A substrate 110 is placed on the substrate holder 16 and its ends are supported by the substrate holder 16. Alignment marks for precise alignment are attached to the substrate 110 and the substrate holder 16. The CCD cameras 18 check if each alignment mark attached to the substrate 110 and the mask 50 is located in the predetermined relative position.

The mask holder 14 and the substrate holder 16 are capable of independently moving and revolving in directions of X, Y, and θ within each plane by aligning the alignment marks between the mask 50 and the substrate 110.

The mask 50 is formed of a magnetic material, such as a nickel-cobalt alloy, an iron-nickel alloy including a 42 alloy. The holes of the mask 50 are aligned in a matrix form at a density of 30 to 250 ppi (pixel per inch). The magnet chuck 12 is, for example, a permanent magnet and is capable of closely attaching the substrate 110 to the mask 50 because of its capability of providing a magnetic field with the mask 50 via the substrate 110 to be adsorbed. The lifting and lowering device not shown in the figure may lift and lower the magnet chuck 12 through the support rod 10. The magnet chuck 12 is useful for securing the display substrate 110 to the magnetic mask 50 in a fully closely attached state and forming pixel patterns with a uniform film thickness with respect to the substrate 110 positioned near the edges of the holes in the mask 50 when forming a film.

Next, a method of producing a display using a mask alignment method according to the present invention will be described.

Inventors of the present invention have confirmed from several experiments that a vector of displacement can be replicated with relatively high precision when the combination of a substrate and a mask is identical. After the completion of an alignment, parameters of the shift (ΔXm, ΔYm, Δθm) at the start of forming a film are measured to realign by correcting the alignment origin by this deviation.

Further, the inventors of the present invention have discovered that the above-mentioned shift levels of the position, ΔXm, ΔYm, and Δθm show values inherent in the alignment stage and to the mask 50 and do not depend on characteristics of the substrate. Thus, previous measurement of the shift levels of the position for each mask 50 (ΔXm, ΔYm, Δθm) enables corrections of the above-mentioned alignment for each mask identification.

The method of producing a display using such alignment method of the present invention has at least the following five steps:

(1) Preparing the display substrate 110 having a plurality of pixel patterns and a mask 50 having holes corresponding to the pixel patterns.

(2) Aligning the mask 50 and the display substrate 110 using the CCD cameras 18 to measure the position between the above-mentioned holes and pixel patterns in a state prior to the fixing of the position between the mask 50 and the display substrate 110.

(3) After the alignment in the second step, fixing the position between the mask 50 and the display substrate 110 with a fastener means, such as a magnetic chuck to measure the position between the holes and the pixel patterns in this condition. After that, calculating shift levels of the position (ΔXm, ΔYm, Δθm) between the position subsequently measured in this step and the position measured in the second step.

(4) Correcting the position between the mask 50 and a second display substrate by feeding back the shift levels of the position (ΔXm, ΔYm, Δθm) calculated in the third step when aligning the mask 50 with respect to a display substrate other than the display substrate 110. More specifically, the display substrate is shifted to (Xd-ΔXm, Yd-ΔYm, θd-Δθm), if the mask 50 is to be aligned on the original position (Xd, Yd, θd).

Upon the completion of the shift of this display substrate, the display substrate 110 and the mask 50 are closely attached to each other to fix the position between the substrate 110 and the mask 50 using a fastener means, such as a magnet chuck. The display substrate is shifted to the positions (Xd, Yd, θd) after passing the step of closely attaching due to the shift levels of the position (ΔXm, ΔYm, Δθm). This enables an alignment with the substrate 110 and the mask 50 in the relative position originally desired.

(5) Forming an evaporant layer on the pixel patterns by depositing evaporant on the above-mentioned pixel patterns through the holes of the mask 50 from an evaporating source arranged on the outside of the mask 50.

A method of obtaining the above-mentioned shift levels of the position, ΔXm, ΔYm, and Δθm for each mask identification is the following: A) Conduct a test run every time a new mask is introduced to previously measure the above-mentioned shift levels of the position, ΔXm, ΔYm, and Δθm. B) Feed back by installing an alignment monitor using a laser displacement gauge or the like for each mask evaporation state.

The following procedures are taken in the method of feeding back the shift levels of the position, ΔXm, ΔYm, and Δθm in B): 1) Read the mask identification and then read out the shift levels of the position corresponding to the identification previously obtained from a memory. 2) Designate the virtual position by adding the shift levels of the position, ΔXm, ΔYm, and Δθm to the predetermined position. 3) Read the current position with CCD cameras and calculate the shift levels of the position with respect to the virtual position. 4) Shift the substrate to the virtual position. 5) Closely attach the mask to the substrate with a magnet chuck to enable evaporation. 6) Reconfirm if the substrate is properly moving by checking the shift levels of the position between the prearranged shift position and the current mask position with the CCD cameras and then start evaporation if it is all right.

Now, specific examples of the present invention will be described in detail with reference to the accompanying drawings.

### EXAMPLE 1

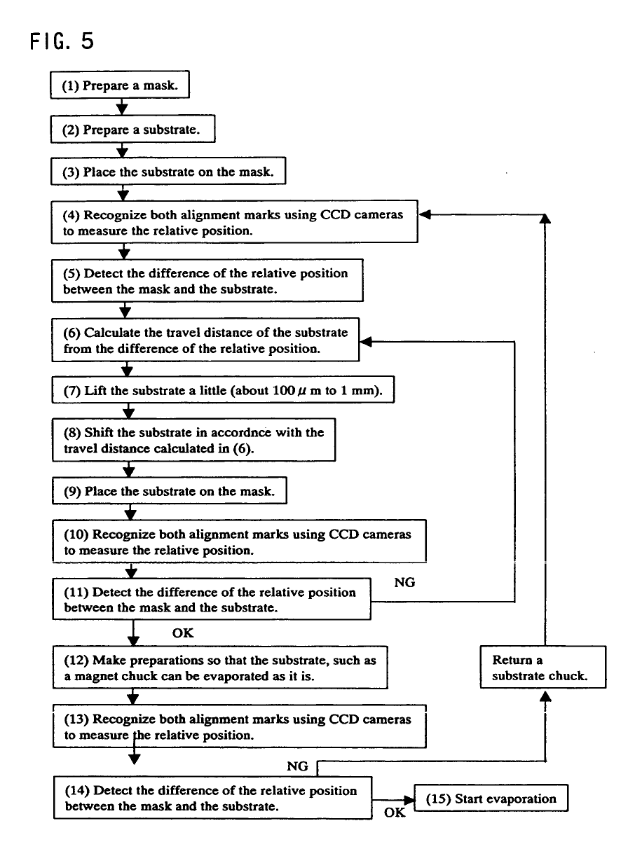

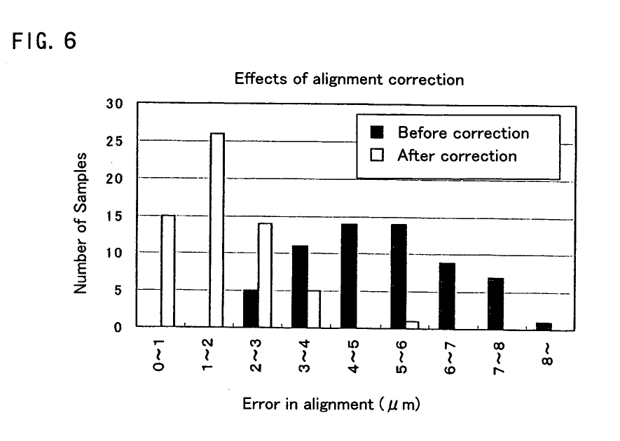

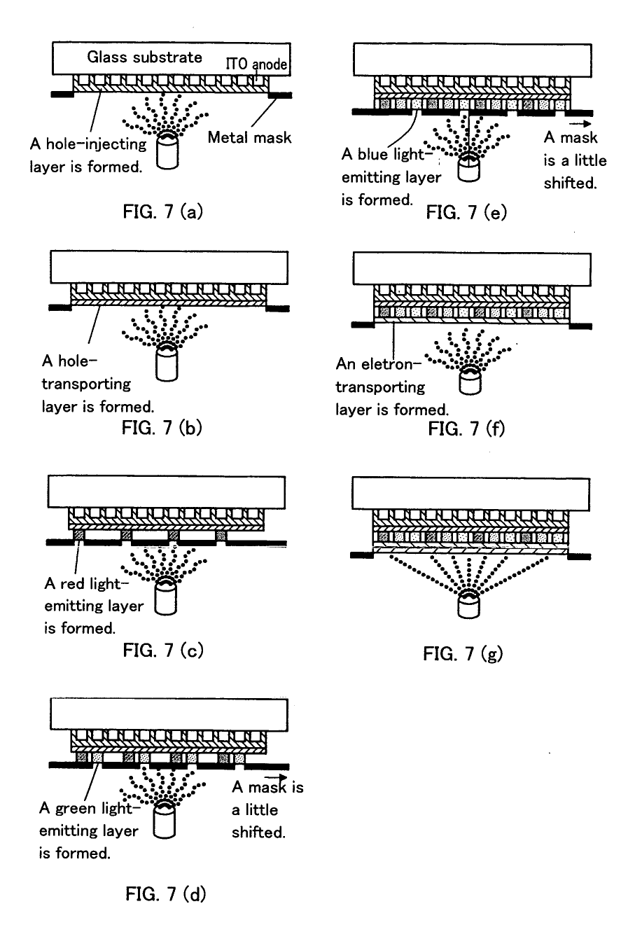

Alignment processes as shown in a flow chart of FIG. 5 are assumed until evaporation is started from the loading of a mask and a substrate into a chamber. Conventionally, the process in which the displacement between the mask and the substrate has occurred at the stage of starting evaporation regardless of alignments with high precision using CCD cameras is the twelfth process.

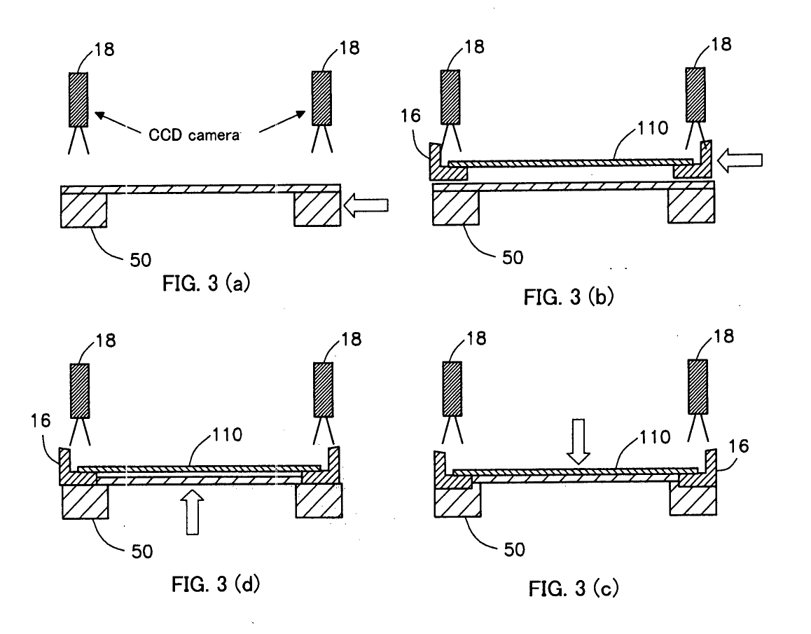

(1) As shown in FIG. 3(a), prepare a mask 50.

(2) As shown in FIG. 3(b), prepare a display substrate 110.

(3) As shown in FIG. 3(c), place the display substrate 110 on the mask 50.

(4) Recognize alignment marks between the mask 50 and the display substrate 110 using CCD cameras 18 to measure the relative position of the mask 50 and the display substrate 110.

(5) Detect the displacement between the mask 50 and the display substrate 110 from the relative position of the mask 50 and the substrate 110 measured in (4).

(6) Calculate the travel distance of the display substrate 110 to be shifted from the displacement detected in (5).

(7) As shown in FIG. 3(d), lift the display substrate 110 a little (about 100 μm to 1 mm).

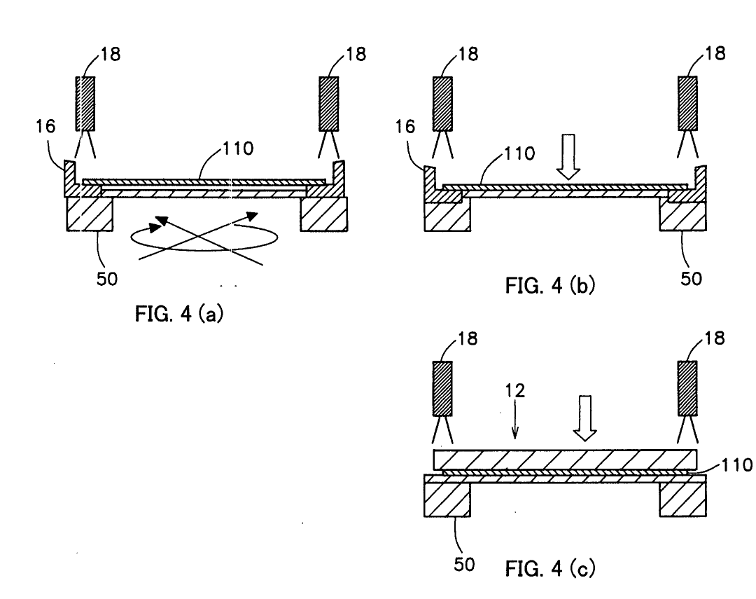

(8) As shown in FIG. 4(a), shift the display substrate 110 upward of the mask 50 in accordance with the travel distance in a state that the mask 50 and the substrate 110 are not in contact to each other.

(9) As shown in FIG. 4(b), place the display substrate 110 on the mask 50.

(10) Recognize the alignment marks using the CCD cameras 18 to measure the relative position.

(11) Detect the displacement between the mask 50 and the display substrate 110 from the relative position of the mask 50 and the substrate 110 measured in (10).

When the displacement between the mask 50 and the substrate 110 is within an acceptable range of alignment precision, the next step (12) is taken. When the displacement exceeds beyond the acceptable range, return to the step (6).

(12) As shown in FIG. 4(c), make preparations so that evaporation can be conducted with respect to the display substrate 110 as it is by fixing the position between the display substrate 110 and the mask 50 using a fastener means, such as a magnet chuck 12, more specifically, by closely attaching the display substrate 110 to the mask 50.

(13) Recognize the alignment marks using the CCD cameras 18 to measure the relative position.

(14) Detect shift levels of the position, ΔXm, ΔYm, and Δθm from the relative position between the mask 50 and the display substrate 110 measured in (13).

When the shift levels of the position, ΔXm, ΔYm, and Δθm between the mask 50 and the substrate 110 detected in (14) are within an acceptable range of alignment precision, the next step (15) is taken to start evaporation. When the shift levels of the position exceed beyond the acceptable range, return to the step (4) after removing a substrate chuck.

Realignment with the mask 50 and the display substrate 110 is conducted when returning to the step (4). In this case, in the step (6), the travel distance of the display substrate 110 to be shifted is calculated by adding the shift levels of the position, ΔXm, ΔYm, and Δθm between the mask and the substrate detected in the step (14). In the step (8), the display substrate 110 is shifted in accordance with the travel distance calculated in the step (6). In this case, there is a high possibility that the alignment precision measured in the step (11) is within the acceptable range because the display substrate 110 has been shifted by the addition of the shift levels of the position, ΔXm, ΔYm, and Δθm detected in the step (14). If there are shift levels of the position, ΔXm, ΔYm, and Δθm with the same mask, the shift levels of the position can be used for the second display substrate, so that production costs can be reduced as well as the improvement of productivity of the display by reducing the frequency of realignment. Particularly, when the mask has an area of not less than 1,200 cm², such as 300 mm×400 mm, the shift levels of the position caused in the step (12) tend to become large because in particular, the flatness of the mask itself is easily lost, but the present invention is especially useful in this case.

In the conventional case, there have been shift levels of the position, ΔXm, ΔYm, and Δθm between the mask and the substrate in the step (12), even when the displacement of the mask and the substrate is within the acceptable range of the alignment precision in the step (11). Measures, such as (A) relaxing the required precision in alignment, (B) increasing the frequency of the alignment, and (c) removing the substrate that is incapable of being aligned with the required precision, have been taken in such a conventional case.

In the alignment method of the example according to the present invention, however, an alignment was conducted from a desired position by correcting the above-mentioned shift levels of the position in previous consideration of the shift levels of the position, ΔXm, ΔYm, and Δθm for each mask.

FIG. 6 is a bar graph showing errors in alignment when a correction is made using the alignment method of the present invention (hereinafter referred to as after correction) and when no corrections are made (hereinafter referred to as before correction). Errors in alignment before correction and after correction were investigated on 61 substrates using all identical masks.

Generally, the acceptable amount in the displacement is not more than ±5 μm, which is approximately the mean value of the displacement measured in the prior art. However, as is clear from FIG. 6, the errors in alignment after correction were within 5 μm on 60 alignments out of 61 alignments, which is the required precision, by being greatly improved compared with errors in alignment before correction. More specifically, it was possible to obtain the value of not more than 5 μm with a rate of 98% by using the alignment method of the present invention, which leads to limit the value under 2 μm on average.

As mentioned above, in the present invention, it has been noted that vector fluctuations are relatively small regardless of different substrates when using identical masks as a result of tracing that the main cause of the vector fluctuations caused by the displacement is the flatness and the degree of parallelization of the mask and its frame or the like. Further, the shift levels of the position (ΔXm, ΔYm, and Δθm) obtained in the first time immediately after the exchange of a mask have been recorded to make corrections using these values from the beginning in the case of the second substrate onward. Since this has eliminated most of the need for realignment, the time required for an alignment has been significantly shortened.

The embodiments of the present have thus been described so far, but the method of producing a display using the alignment method of the present invention is not limited to the above-mentioned embodiments and examples. The present invention includes all displays for forming a film using the mask alignment method in the production processes without the limitation of OLED displays or liquid crystal displays. Formation of a film in this specification means a wide range of forming a film including vacuum deposition, sputtering and chemical vapor deposition. And all of the formation of a film using the mask alignment method is within the scope of the present invention. Moreover, a mask used for the mask alignment method in the present invention is not particularly limited, but may include a mask other than made of a metal. A method of moving a substrate when aligning a mask and a substrate is included in the above-mentioned examples, but similar effects can be obtained even if the method of moving a mask is applied.

The method of producing a display using the mask alignment which has been described so far is capable of rapidly forming RGB (Red, Green, Blue) patterns separately with accuracy without the deterioration of visual quality and providing a high-quality big screen OLED display with low costs by relaxing requirements for mechanical precision of production equipment.

While the embodiments of the present invention have thus been described with reference to the drawings, it should be understood that the present invention be not limited to the embodiments shown in the drawings. Various changes, modifications, and improvements can be made to the embodiments on the basis of knowledge of those skilled in the art without departing from the scope of the present invention.

1. A method of producing a display comprising the steps of:
(1) preparing a first display substrate having a plurality of pixel patterns and a mask having a plurality of holes corresponding to the pixel patterns;
(2) aligning the mask with the first display substrate and measuring the position between the holes and the pixel patterns before fixing the position between the mask and the first display substrate;
(3) fixing the position between the mask and the first display substrate and measuring the position between the holes and the pixel patterns in this situation to calculate shift levels of the position between the position measured and the position measured in the second step;
(4) adjusting the position between the mask and a second display substrate by feeding back the shift levels of the position calculated in the third step when aligning the mask and the second display substrate; and
(5) forming an evaporant layer on each pixel pattern by depositing evaporant on the pixel patterns via the holes of the mask from an evaporating source provided on the outside of the mask.

2. The method according to claim 1, wherein the evaporant layer is an organic layer.

3. The method according to claim 1, wherein the evaporant layers include a red light-emitting organic layer, a green light-emitting organic layer, and a blue light-emitting organic layer.

4. The method according to claim 1, wherein an area of the mask is not less than 1,200 cm².

5. The method according to claim 1, wherein the mask is formed of a magnetic material.

6. The method according to claim 1, wherein holes of the mask are aligned in a matrix form at a density of 30 to 250 ppi.
